(19) United States
(12) Patent Application Publication
(10) Pub. No.: US 2007/0176199 A1
(43) Pub. Date: Aug. 2, 2007

(54) Nitride-based group III-V semiconductor substrate and fabrication method therefor, and nitride-based group III-V light-emitting device

(75) Inventor: Masatomo Shibata, Tsuchiura (JP)

Correspondence Address: FOLEY AND LARDNER LLP;SUITE 500, 3000 K STREET NW, WASHINGTON, DC, 20007, US

(73) Assignee: HITACHI CABLE, LTD.

(21) Appl. No.: 11/449,786

(22) Filed: Jun. 9, 2006

(30) Foreign Application Priority Data
Jan. 27, 2006 (JP) 2006-019506

(51) Int. Cl. H01L 29/20; H01L 21/20

(52) U.S. Cl. 257/103; 438/479; 438/483; 438/46; 257/615

(57) ABSTRACT

A nitride-based group III-V semiconductor substrate has an as-grown surface on the surface thereof; and a flat surface on the back surface of the substrate. The c-axis of a nitride-based group III-V semiconductor crystal composing the substrate is substantially perpendicular to the surface of the substrate or inclined at a predetermined angle to the surface of the substrate.

The present application is based on Japanese patent application No. 2006-019506, the entire contents of which are incorporated herein by reference.

### BACKGROUND OF THE INVENTION

1. Field of the Invention

This invention relates to a nitride-based group III-V semiconductor substrate and a fabrication method therefor, and a nitride-based group III-V light-emitting device. In particular, it relates to a nitride-based group III-V semiconductor substrate, which has small variation in wavelength of light emission of a light-emitting device made therefrom, and a method for fabricating the nitride-based group III-V semiconductor substrate, and a nitride-based group III-V light-emitting device, which has excellent in-plane-of-substrate uniformity in the wavelength of light emission.

2. Description of the Related Art

Nitride semiconductor materials are used in the fabrication of short-wavelength light-emitting devices, especially blue light-emitting diodes (LEDs) because of sufficiently large forbidden bandwidth and direct band-to-band transition. Also, shorter-wavelength ultraviolet LEDs, or white LEDs made by combining these LEDs and fluorescent substances have recently been begun to be practically used.

Generally, semiconductor devices are fabricated by homo-epitaxial growth that uses as its underlying substrate a substrate with the same lattice constant and linear expansion coefficient as those of a crystal to be epitaxially grown thereover. For example, a GaAs monocrystalline substrate is used as a substrate for epitaxial growth of GaAs or AlGaAs.

For only nitride-based group III-V semiconductor crystals, however, it has hitherto been impossible to make a nitride-based group III-V semiconductor substrate with practically sufficient size and properties. For this reason, most of nitride-based light-emitting diodes hitherto practically used have been made by hetero-epitaxial growth of nitride-based group III-V semiconductor crystals over a sapphire substrate with a lattice constant close thereto using metal organic vapor phase epitaxy (MOVPE). Thus there arise various problems resulting from hetero-growth.

For example, the problem arises of large warpage of the substrate after epitaxial growth, caused by the difference between sapphire substrate and GaN linear expansion coefficients. This causes, for example, cracks in the substrate in photolithography and chip fabrication steps after epitaxial growth, and therefore a decline in yield.

Also, because of the difference between sapphire, substrate and GaN lattice constants, monocrystalline growth of nitride crystals requires deposition of a buffer layer at lower temperatures than original crystal growth temperature, which causes crystal growth time to be lengthened. Further, in growth over the sapphire substrate, many dislocations of 10⁸-10⁹ cm⁻² are caused in the GaN epi-layer, by the difference between sapphire substrate and GaN lattice constants. These dislocations disturb light-emitting device power and reliability. In conventional blue light-emitting diodes, there have hitherto been few problems with dislocations, but it is predicted that because in the future, higher power blue LEDs will be demanded, and ultraviolet LED realization will facilitate making its wavelength short, the dislocations will have large effects on device properties, and therefore that measures therefor will have to be taken.

To overcome these problems, a GaN self-standing monocrystalline substrate has recently been developed. As a method for fabricating the GaN self-standing substrate, JP-A-11-251253, for example, discloses that the GaN self-standing substrate is obtained by forming over an underlying substrate a mask with an opening, for using ELO (Epitaxial Lateral Overgrowth), i.e., for laterally growing from the opening and forming a GaN layer with few dislocations over the sapphire substrate, and then removing (e.g., etching) the sapphire substrate.

Also, as a method that is developed from the ELO, there is FIELO (Facet-Initiated Epitaxial Lateral Overgrowth) (see, for example, Akira Usui et. al., “Thick GaN Epitaxial Growth with Low Dislocation Density by Hydride Vapor Phase Epitaxy”, Jpn. J. Appl. Phys. Vol. 36(1997) p.p. L899-L902). The FIELO is common with the ELO in that selective growth is performed using a silicon oxide film, but it is different therefrom in that in the selective growth a facet is formed in the mask opening. By forming the facet, the propagation direction of the dislocations is changed, so that the number of through-dislocations that reach the top surface of the epitaxially grown layer is decreased. By using the FIELO, growing a thick film GaN layer over an underlying substrate such as sapphire, and then removing the underlying substrate, it is possible to obtain a good-quality GaN self-standing substrate with relatively few crystal defects.

Besides, as a method for fabricating the GaN self-standing substrate with low dislocations, there is DEEP (Dislocation Elimination by the Epi-growth with Inverted-Pyramidal Pits) (see, for example, Kensaku Motoki et. al. “Preparation of Large Freestanding GaN Substrates by Hydride Vapor Phase Epitaxy Using GaAs as a Starting Substrate”, Jpn. J, Appl. Phys. Vol. 40(2001) p.p. L140-L143, and JP-A-2003-165799). The DEEP uses a silicon nitride mask patterned on a GaAs substrate to grow GaN, intentionally form in crystal surface plural pits surrounded by facet planes, accumulate dislocations at the bottom of the pits and thereby form the other region with low dislocations.

Also, as a method for fabricating a nitride-based group III semiconductor substrate with low dislocation density, JP-A-2003-178984 discloses that a GaN layer is formed over a sapphire c-plane ((0001) plane) substrate, followed by formation of a titanium film thereover, and subsequent heat treatment of the substrate in atmosphere containing hydrogen gas or hydrogen-containing compound gas, to form voids in the GaN layer, and form a GaN semiconductor layer over the GaN layer.

The GaN substrate obtained by using these ELO and DEEP, growing with HVPE the GaN film over the hetero-substrate, and then separating the GaN layer from the underlying substrate is used mainly in the development of laser diodes (LDs) that especially require a low-dislocation crystal, but has recently also been used as a substrate for LEDs. The GaN substrate obtained by these methods has morphologies such as pits, hillocks, etc. typically appearing in its as-grown surface surface, and has pear-skin-like rough surface on its back surface. For this reason, it is difficult to grow thereover an epitaxial layer for device fabrication, and therefore the surface and back surface of the substrate are generally polished and mirror-finished, to be used in the device fabrication.

In Si or GaAs semiconductor substrates, which have conventionally been used, no problem arises that crystalline orientation distribution is significantly different in the surface of the substrate, because the substrate to be fabricated is cut out of a crystal ingot. However, because in GaN self-standing substrates, the thick crystal epitaxially grown over the hetero-substrate is separated therefrom after the growth to fabricate the substrate, strain that accumulates in the epi-layer during the crystal growth is often released simultaneously with the separation of the underlying substrate, so as to warp the substrate. For this reason, crystalline orientation distribution in the surface of the substrate occurs in the plane of the substrate to reflect the effect of the substrate warpage. This will be explained with reference to FIGS. 8A-8E.

FIG. 8A is a simplified cross-sectional view illustrating an ideal GaN substrate crystalline orientation distribution, where the arrows denote c-axis orientations, respectively, of the crystal. In the actual substrate, however, its back surface warps convexly. In this case, the crystalline orientation of the substrate is bent according to the warpage of the substrate, so that the crystalline orientation of the warped substrate has distribution in the substrate as shown in FIG. 8B. For this reason, the double-sided polished GaN substrate is presently often used, but because this substrate which looks flat is that made by only double-sidedly flattening the originally-warped substrate, the crystalline orientation inside the substrate has distribution resulting from the warpage, as shown in FIG. 8C.

Although the all-c-plane just-substrate has been explained above, an off-substrate whose crystalline orientation is intentionally inclined is often used as a substrate for light-emitting diodes. In this case, the illustrated arrows above only have to be slightly inclined in a constant direction. The off-substrate may be considered similarly to the just-substrate.

Also, because the fabrication method grows and peels the thick-film epitaxial growth crystal one by one, the GaN substrate has a cross-sectional shape to reflect film thickness distribution during crystal growth. That is, when the film thickness is uniform in the plane, the as-grown substrate surface is concave as shown in FIG. 8B. But, in practice, it is difficult to cause crystal growth to have entirely the same velocity in the plane of the substrate, and consequently the distribution occurs in the film thickness. When the film thickness distribution during crystal growth is thin in the middle and thicker with more peripheral portion, the concave degree of the surface of the substrate is large. Conversely, when the film thickness distribution during crystal growth is thick in the middle and thinner with more peripheral portion, the surface of the substrate can also be convex surface as shown in FIG. 8D. Typically, in view of easy process steps, and other actual semiconductor substrate examples, it is technical common practice to use well-flattened surface of the substrate, and in the fabrication of the GaN substrate used with as-grown surface, to flatten its surface shape as much as possible, its film thickness distribution during crystal growth is controlled to be slightly thick in the middle as shown in FIG. 8E.

It is found as a result of study of the inventors, however, that the above-explained GaN substrate made by flattening the surface of the warped crystal, or the GaN substrate with the as-grown surface approximated to flat surface by controlling its film thickness distribution has large in-plane-of-substrate variation in wavelength of light emission of a light-emitting device made therefrom, and that there is the problem of low yield for the device with designed wavelength to be obtained.

### SUMMARY OF THE INVENTION

Accordingly, it is an object of this invention to provide a nitride-based group III-V semiconductor substrate, which obviates the above problems and specifically, which has small variation in wavelength of light emission, even when there is variation in crystalline orientation due to crystal warpage in the plane of the substrate, and a method for fabricating the nitride-based group III-V semiconductor substrate, and a nitride-based group III-V light-emitting device, which has excellent in-plane-of-substrate uniformity in the wavelength of light emission.

Wavelengths of light emission of light-emitting devices, such as those with an MQW (Multi-Quantum Well) including an InGaN layer, depend largely on composition and film thickness of the InGaN layer. The growing velocity, which affects the composition and film thickness of the InGaN layer, has dependency on an off-angle of an underlying GaN substrate. Accordingly, it has hitherto been believed, of course, that when the light-emitting device is made on the GaN substrate with crystalline orientation distribution in the plane of the substrate, there appears an in-plane-of-substrate distribution of the light emission wavelengths, depending on the crystalline orientation distribution.

This inventor finds out, however, that the variation of the light emission wavelength is made small by holding substantially constant the step density of atoms present in the crystal growth interface, even if there is off-angle distribution in the underlying GaN substrate, departing from the conventional technical common knowledge that because the dependence of the InGaN layer composition and growing velocity on the off-angle of the underlying GaN substrate is caused by the dependence of the step density of atoms present in the crystal growth interface on the off-angle of the GaN substrate, the crystal growth interface should be (macroscopically) flattened.

### (1) According to a first aspect of the invention, a nitride-based group III-V semiconductor substrate comprises;

an as-grown surface on a surface of the substrate; and

a flat surface on a back surface of the substrate,

wherein a c-axis of a nitride-based group III-V semiconductor crystal composing the substrate is substantially perpendicular to the surface of the substrate.

In the above invention (1), the following modifications and changes can be made.

(i) The surface of the substrate comprises a concave surface.
(ii) The concave surface on the surface of the substrate is approximated to a spherical surface, and an angle difference between a c-axis orientation of the crystal at an arbitrary point on the surface of the substrate and a normal to a tangent to the spherical surface at the arbitrary point is not more than 1°.
(2) According to a second aspect of the invention, a nitride-based group III-V semiconductor substrate comprises:

an as-grown surface on the surface of the substrate; and

a flat surface on a back surface of the substrate,

wherein a c-axis of a nitride-based group III-V semiconductor crystal composing the substrate is inclined at a predetermined angle to the surface of the substrate.

In the above invention (2), the following modifications and changes can be made.

(iii) The surface of the substrate comprises a concave surface.

In the above invention (1) or (2), the following modifications and changes can be made.

(iv) The substrate comprises a self-standing substrate.
(v) The substrate comprises a substrate to be used for a light-emitting diode.
(vi) The nitride-based group III-V semiconductor crystal comprises a composition expressed by InₓGa_{y}Al_{1-x-y}N (where 0≦x≦1, 0≦y≦1, and 0≦x+y≦1).
(vii) The substrate comprises a shape with a diameter of 50 mm or more, and a thickness of 200 μm or more in its middle portion, and a difference in thickness of 100 μm or less between the middle portion and its peripheral portion.
(viii) The substrate comprises a carrier concentration of 5×10¹⁷ cm⁻³ or more.
(ix) The substrate comprises a dislocation density of 1×10⁸ cm⁻² or less in its surface.
(3) According to a third aspect of the invention, a method of fabricating a nitride-based group III-V semiconductor substrate comprises the steps of:

growing a nitride-based group III-V semiconductor film on a hetero-substrate that comprises a c-plane on its surface, and then depositing a metallic film thereon;

thermally treating the substrate with the metallic film deposited thereon in an atmosphere containing hydrogen gas or hydrogen-containing compound gas, to form a void in the nitride-based group III-V semiconductor film;

depositing a nitride-based group III-V semiconductor crystal thereon;

separating the substrate from the nitride-based group III-V semiconductor crystal, to obtain the nitride-based group III-V semiconductor crystal with a c-axis substantially perpendicular to the surface; and

flattening the back surface of the nitride-based group III-V semiconductor crystal.

Herein, “flattening” is used as a term that means various flattening processes such as grinding, lapping and polishing.

(4) According to a fourth aspect of the invention, a method of fabricating a nitride-based group III-V semiconductor substrate comprises the steps of:

growing a nitride-based group III-V semiconductor film on a hetero-substrate that comprises an off-angle, and then depositing a metallic film thereon;

thermally treating the substrate with the metallic film deposited thereon in an atmosphere containing hydrogen gas or hydrogen-containing compound gas, to form a void in the nitride-based group III-V semiconductor film;

depositing thereon a nitride-based group III-V semiconductor crystal that comprises an off-angle;

separating the substrate from the nitride-based group III-V semiconductor crystal, to obtain the nitride-based group III-V semiconductor crystal with a c-axis inclined at a predetermined angle to the surface; and

flattening the back surface of the nitride-based group III-V semiconductor crystal.

In the above invention (3) or (4), the following modifications and changes can be made.

(x) The depositing step of the nitride-based group III-V semiconductor crystal is performed by HVPE.
(xi) The nitride-based group III-V semiconductor crystal comprises a gallium nitride crystal.
(xii) The hetero-substrate comprises sapphire.
(5) According to a fifth aspect of the invention, a nitride-based group III-V light-emitting device comprises:

an epitaxial layer formed on the nitride-based group III-V semiconductor substrate as defined in any one of the above inventions (1)-(4), the epitaxial layer comprising a nitride-based group III-V semiconductor crystal

### <Advantages of the Invention>

The nitride-based group III-V semiconductor substrate according to this invention is capable of substantially reducing in-plane-of-substrate variation in wavelength of light emission of an LED device with an MQW (Multi-Quantum Well) including an InGaN layer made therefrom.

Also, the nitride-based group III-V semiconductor substrate fabrication method according to this invention is capable of omitting surface flattening, and therefore not only of making fabrication process simpler than in the prior art, and substantially reducing fabrication cost, but also of reducing the incidence of defects due to flattening.

Further, the nitride-based group III-V light-emitting device according to this invention is capable of having excellent in-plane-of-substrate uniformity in the wavelength of light emission,

### BRIEF DESCRIPTION OF THE DRAWINGS

The preferred embodiments according to the invention will be explained below referring to the drawings, wherein:

FIGS. 1A-1F are diagrams showing a process for fabricating a GaN self-standing substrate in Example 1 according to the invention;

FIG. 2 is a plan view showing an orientation and magnitude of c-axis inclination in the GaN self-standing substrate of Example 1;

FIG. 3 is a diagram showing the relation between the GaN self-standing substrate and c-axis inclination in the GaN self-standing substrate of Example 1;

FIG. 4 is a cross-sectional view showing LED epi-structure in Example 2 according to the invention;

FIGS. 5A-5F are diagrams showing a process for fabricating a GaN self-standing substrate in Example 3 according to the invention; and

FIG. 6 is a plan view showing an orientation and magnitude of c-axis inclination in the GaN self-standing substrate of Example 3;

FIG. 7 is a diagram showing the relation between the GaN self-standing substrate and c-axis inclination in the GaN self-standing substrate of Example 3; and

FIG. 8A is a diagram showing an ideal GaN substrate crystalline orientation distribution;

FIG. 8B is a diagram showing an actual GaN substrate crystalline orientation distribution;

FIG. 8C is a diagram showing a GaN substrate crystalline orientation distribution after flattening of FIG. 8B;

FIG. 8D is a diagram showing an actual GaN substrate crystalline orientation distribution where film thickness distribution is thick in the middle and thin in the periphery; and

FIG. 8E is a diagram showing an ideal GaN substrate crystalline orientation distribution where film thickness distribution is slightly thick in the middle.

### DETAILED DESCRIPTION OF THE PREFERRED EMBODIMENTS

### Preferred Embodiments

A GaN-based self-standing substrate in a preferred embodiment according to the invention is a self-standing semiconductor monocrystalline substrate obtained by growing a GaN-based semiconductor monocrystal on a hetero-substrate and then separating it therefrom. The substrate has an as-grown and concave surface on its surface, and a flattened surface on its back surface, and a c-axis of the crystal is oriented substantially perpendicular or inclined at a predetermined angle to the surface of the substrate. The respective points of the preferred embodiment will be explained in detail below.

Self-Standing Substrate

The self-standing substrate herein refers to a substrate that is capable of not only holding the shape of itself, but also having strength so as not to cause inconvenience in handling. To have such strength, it is preferred that the thickness of the self-standing substrate is 200 μm.

As-Grown Surface of the Substrate

The substrate has the as-grown surface on its surface. Here, the as-grown surface means a surface of a crystal in an as-grown state prior to mechanical fabrication such as cutting, flattening, etc. The mechanical fabrication mentioned here does not involve etching and cleaning for removing dirt on the surface.

Use of the substrate surface as the as-grown surface allows preventing a decrease in substrate manufacturing yield in the flattening step. The c-plane substrate of GaN has a substantial difference in properties between its surface and back surface. The Ga plane of the surface is hard compared to the N plane of the back surface, so that the velocity of flattening is lower. It is also chemically very stable and is difficult to etch, so that it is subject to flaws such as scratches. Accordingly, if the Ga plane flattening step is omitted, the substrate manufacturing yield can be enhanced to ensure a substantial decrease in cost. Further, because the Ga plane is difficult to flatten, there is the problem that fabrication strain due to flattening tends to remain. During epi-layer growth on the substrate, the remaining fabrication strain disturbs the morphology of the epi-layer surface, or causes new crystal defects in the epi-layer. Use of the substrate in the as-grown state allows no fabrication strain to remain, and therefore no problem arises due to the aforementioned remaining fabrication strain.

Also, in substrates for LDs, the flatness of the substrate surface is important because of need of microfabrication in device fabrication process, but in substrates for LEDs, cost competitiveness is more important because of not so much need of microfabrication. For this reason, it is preferred that a substrate with an as-grown surface not flattened which has conventionally been done is used as the LED substrate.

Concave Surface of the Substrate

The substrate has concave surface on its surface. The reason for this is because the GaN substrate obtained by growing the GaN-based semiconductor monocrystal on the hetero-substrate and then separating it therefrom tends to warp so as to form convex surface on its back surface. The crystalline orientation of the warped substrate is rate-determined by the shape of the back surface of the substrate, but not dependent on concave and convex directions of the surface of the substrate. Specifically, in the case of back surface convex warpage of the substrate, the distribution of the c-axes of the crystal is not affected by surface shape which varies according to film thickness distribution of the crystal, and is perpendicular to the curved back surface.

Inclination of the C-Axes of the Crystal: Substantially Perpendicular or at a Predetermined Angle to the Surface of the Substrate

As mentioned previously, in epitaxial growth for fabricating light-emitting devices, to reduce in-plane-of-substrate variation in wavelength of light emission, it is desirable that the step density of atoms present in the crystal growth interface during the epitaxial growth is held uniform in the plane of the substrate. To this end, the c-axis of the crystal at any point of the substrate is always oriented, at that point, substantially perpendicular to the surface of the substrate, or at a constant off-angle to the surface of an off-substrate. Accordingly, the substrate with convexly warped surface on its back surface has concave surface on its surface, and the c-axis of the crystal is oriented substantially perpendicular to the surface of the substrate. Here, the substrate has not a little morphology called hillocks or terraces in its as-grown surface, which results in no smooth surface. Accordingly, the concave surface of the substrate means that when the surface is approximated to a curved surface, this approximately curved surface may be concave, and the phrase “substantially perpendicular” means that “perpendicular” may be relative to the approximately curved surface and include variations on the order of ±1°. In the case of the off-substrate, the aforementioned “perpendicular” may be changed to “a predetermined angle”.

Specifically, it is desirable that when the surface of the substrate is approximated to a spherical surface, the substrate has an angle difference of not more than 1° between the c-axis orientation of the crystal at any point on the surface of the substrate and the normal to the approximately spherical surface of the substrate at the same point. This is because in case the same angle difference exceeds 1°, when that point is microscopically observed, micro inclined surface appears on the surface, so that it is difficult to keep the step density of atoms present in the crystal growth interface approximately constant in the plane of the substrate. If the substrate is not an off-substrate, and the substrate is in an axis symmetry shape, the normal to the approximately spherical surface of the substrate in the middle of the substrate is in the same direction as the c-axis orientation, and the angle difference between the c-axis orientation of the crystal at any point on the surface of the substrate and the normal to the approximately spherical surface of the substrate at the same point is the largest in the outermost periphery of the substrate. In the case of the off-substrate, the angle difference is the largest in the outermost periphery of the substrate, and at one point on a line which passes through the center and in an off-direction. Accordingly, in other words, it is desirable that the angle difference between the c-axis orientation of the crystal and the normal to the approximately spherical surface of the substrate falls within the variation range of not more than ±1° in the plane of the substrate.

Back Surface of the Substrate

The substrate has flattened surface on its back surface. The reason for flattening the back surface is because of good close contact between the substrate and a susceptor during epitaxial growth on the substrate. If the entire back surface of the substrate is not in uniform contact with the susceptor, the thermal conduction from the susceptor is inhomogeneous, to make substrate temperature inhomogeneous in its plane during epitaxial growth. Substrate temperature variation in its plane causes variations in crystal growth velocity, composition and impurity concentration, and makes impossible epitaxial growth with high property homogeneity in the plane. There exists an epitaxial growth apparatus of face-down type that does not bring the substrate back surface into close contact with the susceptor. But in this case, a thermally homogenizing plate is commonly placed on the back surface of the substrate, so that if there is variation in the distance between the back surface of the substrate and the thermally homogenizing plate, the aforementioned temperature variation is caused to affect the property homogeneity.

Also, the GaN substrate back surface (N plane) is easy to flatten in comparison to its surface (Ga plane), so that the flattening of the back surface causes neither an increase in the number of process steps nor a decrease in yield in comparison to that of the surface. The back surface may be flattened so that the good close contact between it and the susceptor is obtained during epitaxial growth, but the back surface does not have to be mirror-finished. That is, it may be lapped or ground, or treatment (etching, etc.) may be applied to this for strain removal.

Dimensions of the Substrate

As dimensions of the substrate, it is desirable that it is in a 50 mm or more diameter circular shape, and is 200 μm or more in its middle thickness, and 100 μm or less in the difference between its middle and peripheral thicknesses. Light-emitting devices, esp. LEDs are versatile devices used in consumer products, and mass-production thereof is indispensable for practical and widespread use. If the diameter of the substrate is 50 mm or more, because a process apparatus for mass-production of a conventional GaAs substrate has already been developed, application is easily made to mass-production lines. Also, the reason for 200 μm or more in the middle thickness of the substrate (in the thinnest thickness of the substrate with a concave surface) is because, at thicknesses of less than 200 μm, the risk for the substrate being broken becomes sharply high during handling of tweezers, etc. The reason for 100 μm or less in the difference between the middle and peripheral thicknesses of the substrate is because the process of the light-emitting device, esp. of photolithography is facilitated. More than 100 μm difference between the middle and peripheral thicknesses of the substrate causes non-uniform resist coating in the photolithographic process, or chipping of the edge of the substrate when a mask is brought into close contact with the substrate with a contact-type mask aligner. Also, the mask pattern fails to be focused uniformly in the plane of the substrate.

Conductivity Type and Carrier Concentration of the Substrate

The conductivity type of the substrate should be controlled appropriately according to devices to be made therefrom, and cannot be determined across the board, but may be an n-type doped with Si, S, O, etc., or a p-type doped with Mg, Zn, etc. The absolute value of the carrier concentration of the substrate should be controlled appropriately according to devices to be made therefrom, and cannot therefore be determined across the board. It is desirable, however, that LED substrates be conductive so that the contact of a back surface electrode can easily be made. To this end, it is desirable that the carrier concentration of the substrate be 5×10¹⁷ cm⁻³ or more. Particularly, because too high a carrier concentration of the LED substrates reduces crystallinity of the substrate and impairs transparency thereof, it is desirable that the carrier concentration of the LED substrates be controlled to be 5×10¹⁷ cm⁻³ or more to 1×10¹⁹ cm⁻³ or less.

Dislocation Density of the Substrate

It is desirable that the dislocation density in the surface of the substrate be 1×10⁸ cm⁻² or less. It is found that a dislocation from the underlying substrate is inherited into a layer epitaxially grown on the substrate. The dislocation in the epi-layer disturbs device properties, so as to degrade reliability. When used mainly in short-wavelength high-power LED or LD applications, it is desirable, from the point of view of no property degradation of these devices and of reliability being maintained, that the dislocation density in the epi-layer, i.e., the dislocation density in the surface of the substrate be 1×10⁸ cm⁻² or less.

Materials for the Substrate

As materials for the substrate in this embodiment, not only GaN but also nitride-based group III-V semiconductors expressed by formula InₓGa_{y}Al_{1-x-y}N (where 0≦x≦1, 0≦y≦1, and 0≦x+y≦1) may be used. As the nitride-based group III-V semiconductors, not only GaN but also AlGaN, InN, or a mixed crystal thereof are practically used. From the point of view of substrate, GaN has the advantage that it is possible to easily obtain its crystal with a certain degree of large aperture and large thickness and that homo-epitaxial growth is also easily possible. Besides, AlN or AlGaN substrates have the advantage of being easy to use. Also, it is desirable that the surface of these substrates comprise a (0001) group III plane. This is because GaN-based crystals have strong polarity, so that the group III plane is more stable chemically and thermally than the group V plane (the nitrogen plane), and thereby facilitates device fabrication.

Method for Fabricating the Substrate

The substrate in this embodiment is obtained by growing a GaN-based semiconductor monocrystal on a hetero-substrate and then separating it therefrom.

It is desirable that the GaN-based semiconductor monocrystal is grown by HVPE (hydride vapor phase epitaxy). This is because the HVPE uses fast crystal growth velocity and is therefore suitable for substrate fabrication which requires thick film growth. Also, the method for growing a GaN-based semiconductor monocrystal and then separating it may use void-assisted separation (VAS). The VAS is excellent in that it is capable of reproducible separation of the substrate with large aperture, and of obtaining the GaN-based self-standing substrate with low dislocation and homogeneous properties. The reason for growing the GaN-based semiconductor monocrystal on the hetero-substrate and then separating it therefrom is because as it stands, the method for growing the GaN-based self-standing substrate with a diameter of φ=2 inches or more and sufficient thickness to withstand handling is limited to a method such as the VAS, or a combination of FIELO and laser lift-off. Also, this method can grow the crystal with sufficient surface morphology to directly grow the epi-layer for LEDs even in the as-grown state.

GaN-Based Light-Emitting Device

The GaN-based self-standing substrate in this embodiment is suitable for epitaxially growing thereon, with MOVPE, a nitride-based group III-V semiconductor crystal for fabricating a light-emitting diode. The substrate with an as-grown surface has morphology with unevenness such as hillocks as mentioned previously, and is therefore more preferable in LED fabrication than in LD fabrication that involves a micro-photolithography process. The LED fabrication does not so much require surface flatness of the substrate as does the LD fabrication, but it is rather important to reduce unit cost of the substrate, and to satisfy this, the substrate with as-grown surface is therefore suitable. The reason for it being desirable to use the MOVPE in epitaxial growth for the LED is because the epitaxial growth technique for achieving high light emission power has been established. By using the GaN-based self-standing substrate in this embodiment to fabricate the LED with an MQW (Multi-Quantum Well) including an InGaN layer, it is possible to substantially reduce in-plane-of-substrate variation in wavelength of light omission of the device.

### EXAMPLE 1

Fabrication of the GaN Self-Standing Substrate with its As-Grown Surface and Flattened Back Surface

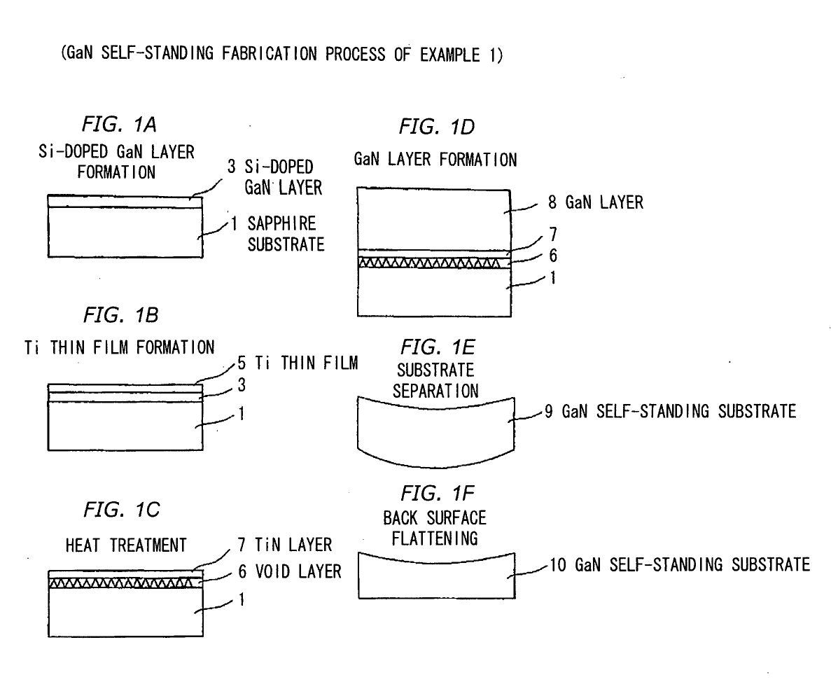

A GaN self-standing substrate is fabricated with the fabrication process shown in FIGS. 1A-1F.

First, a Si-doped GaN layer 3 is grown, with MOVPE, by 0.5 μm, over a 2 inch diameter c-plane just sapphire substrate 1, via a 20 nm low-temperature grown buffer layer (FIG. 1A). The growth conditions are: normal pressure, 600° C. substrate temperature during buffer layer growth, and 1100° C. substrate temperature during epi-layer growth. TMG is used as group III raw material, NH₃ as group V raw material, and monosilane as dopant. A mixture of hydrogen and nitrogen gases is used as carrier gas. The crystal growth velocity is 4 μm/h. The carrier concentration in the epi-layer is 2×10¹⁸ cm⁻³.

Next, over this Si-doped GaN layer 3 is deposited a 20 nm thick metal Ti thin film 5 (FIG. 1B). The substrate thus obtained is placed in an electrical furnace, for heat treatment in a 20% NH₃-containing H₂ gas stream at 1050° C. for 20 min. Consequently, the GaN layer 3 is partially etched to form a high-density void layer 6, while the Ti layer is nitrided to form a TiN layer 7 with high-density submicron holes formed in its surface (FIG. 1C).

This substrate is placed in an HVPE furnace. Using a supply gas containing a raw material gas comprising 8×10⁻³ atm GaCl and 4.8×10⁻² atm NH₃ in a carrier gas, a 600 μm thick GaN layer 8 is grown (FIG. 1D). Here, the carrier gas uses N₂ as containing 5% of H₂. The growth conditions of the GaN layer 8 are: normal pressure and 1080° C. substrate temperature. Also, in the step of growing the GaN crystal, the substrate region is supplied with SiH₂Cl₂ as doping raw material, to thereby be doped with Si. After the growth ends, in the process of cooling the HVPE apparatus, the GaN layer 8 is spontaneously separated at the void layer 6 from the underlying substrate, which results in a GaN self-standing substrate 9.

The GaN self-standing substrate 9 obtained is convexly warped to its back surface, while being in a concave shape on its surface to reflect the shape of the back surface (FIG. 1E). That is, the film thickness distribution in the plane of the GaN self-standing substrate 9 at this point is substantially uniform. Next, the back surface of the GaN self-standing substrate 9 obtained is lapped and flattened on a metallic surface plate with diamond slurry. Consequently, a GaN self-standing substrate 10 with film thickness distribution being thin in the middle and thick in the periphery is obtained (FIG. 1F). When the thickness of the substrate is measured with a dial gauge, it is 305 μm in its middle, and 365 μm in its peripheral thickest portion.

The back surface (flat surface) of this substrate is taken as the reference plane. The c-axis inclination distribution in the substrate surface is obtained by X-ray diffraction measurement. It is found that the c-axis inclination distribution measured at 5 points in the plane of the substrate is such that the c-axes are all directed to the middle of the substrate, having variations of ±0.3° in the plane.

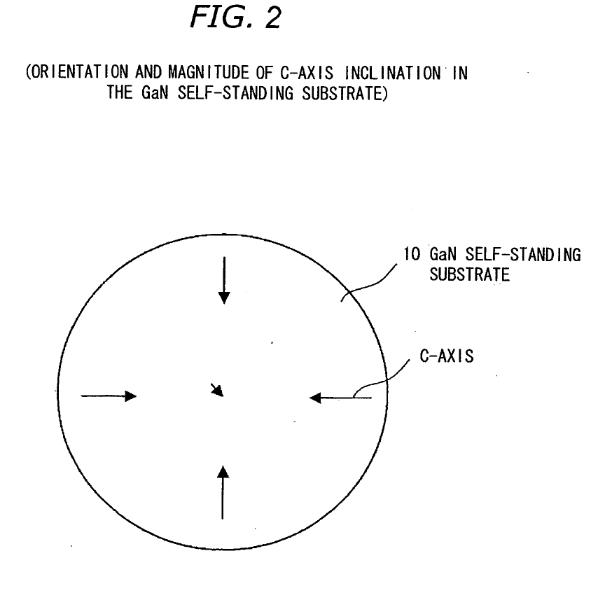

FIG. 2 shows the c-axis inclination distribution obtained from the measurements of this GaN self-standing substrate 10. The arrows in the figure show a vector indicating a c-axis inclination of the crystal at that point, where the direction of the arrows denotes the inclination and the length thereof the magnitude of the inclination.

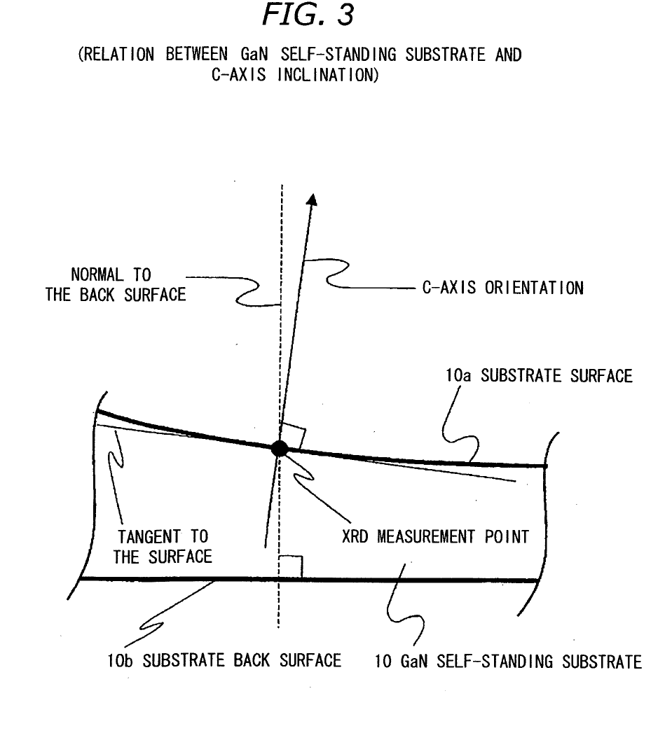

The c-axes of the crystal relative to the back surface flat surface form the inclination distribution as shown in FIG. 2. Because of the concavely warped substrate surface, the c-axis orientations at the measurement points are always perpendicular to the substrate surface at any position of the substrate. This relation will be explained based on FIG. 3.

FIG. 3 shows the relation between the substrate and measured c-axis inclination in the GaN self-standing substrate 10. As shown, the c-axis of the GaN crystal measured at the substrate surface 10a is inclined relative to the substrate back surface 10b, so that the orientation and magnitude of the inclination are different at each measurement point. But the c-axis is always held perpendicular at any measurement point to the tangent thereat to the substrate surface 10a.

When the dislocation density of this GaN self-standing substrate 10 is evaluated with the dark spot density of cathode luminescence, it is 3.5×10⁶ cm⁻² in the substrate middle and 4.2×10⁶ cm⁻² on average of 9 points in the plane. Also, calculation of the carrier concentration of the GaN self-standing substrate 10 from substrate sheet resistance obtained by eddy-current measurement, mobility and substrate thickness yields 3.0×10¹⁸ cm⁻³.

### EXAMPLE 2

Epitaxial Layer Formation for Blue LEDs

Using depressurizing MOVPE, over the GaN self-standing substrate 10 obtained in Example 1 is formed an epitaxial layer for blue LEDs.

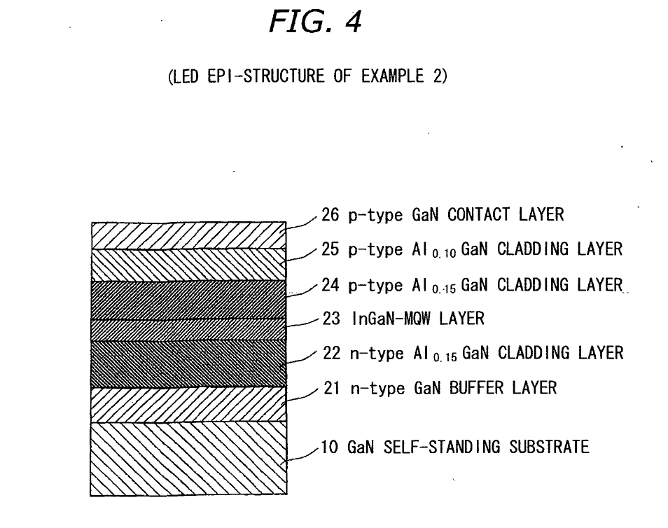

FIG. 4 shows an epitaxial layer configuration formed. The layers grown are as follows: Sequentially from the GaN self-standing substrate 10 side, a Si-doped n-type GaN buffer layer 21, a Si-doped n-type Al_{0.15}GaN cladding layer 22, a 3-period InGaN-MQW layer 23, a Mg-doped p-type Al_{0.15}GaN cladding layer 24, a Mg-doped p-type Al_{0.10}GaN cladding layer 25, and a Mg-doped p-type GaN contact layer 26.

Next, PL (photoluminescence) measurement of this LED epitaxial layer is performed. The wavelength of light emission of the PL has maximum variations of ±2 nm in the plane, which are sufficiently small in comparison to a comparison example as will be explained next.

### COMPARISON EXAMPLE

Fabricating a Double-Sided Flattened GaN Self-Standing Substrate

The surface of the GaN self-standing substrate 10 obtained in the same method as in Example 1 is lapped and mirror-finished with diamond slurry. In this stage, the GaN self-standing substrate is in a flat shape on both its front and back surfaces, but the c-axis inclination of the crystal occurs similarly to Example 1. Specifically, in the comparison example, because the surface is flattened, the angles between the substrate surface and the c-axes have variations of ±0.3° in the substrate plane.

On the surface of the double-sided flattened substrate is grown an LED epitaxial layer similar to that of Example 2. When the in-plane-of-substrate distribution of PL light emission wavelengths is examined, it has maximum variations of ±8.5 nm in the plane.

### EXAMPLE 3

Fabricating a GaN Self-Standing Substrate with its As-Grown Surface and Flattened Back Surface and with an Off-Angle

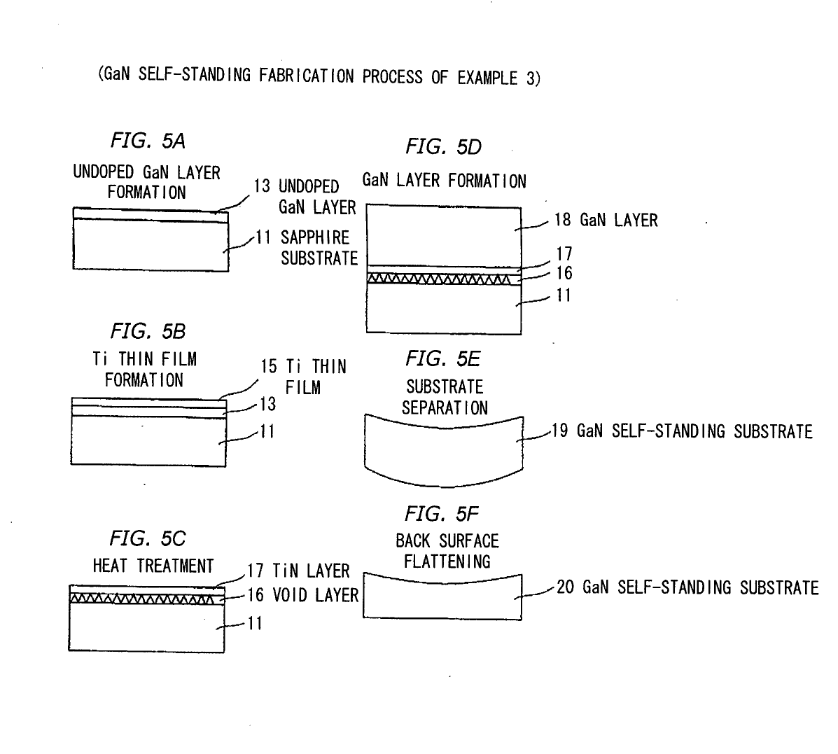

A GaN self-standing substrate is fabricated with the fabrication process shown in FIGS. 5A-5F.

First, an undoped GaN layer 13 is grown, with MOVPE, using TNG and NH₃ as raw material, by 300 nm, over a commercial 2.5 inch diameter monocrystalline c-plane sapphire substrate 11 with 0.35° off-angle in an m-axis direction (FIG. 5A).

Next, over this undoped GaN layer 13 is deposited a 25 nm thick metal Ti thin film 15 (FIG. 5B). The substrate thus obtained is placed in an electrical furnace, for heat treatment in a 20% NH₃-containing H₂ gas stream at 1000° C. for 25 min. Consequently, the GaN layer 13 is partially etched to form a high-density void layer 16, while the Ti layer is nitrided to form a TiN layer 17 with high-density submicron holes formed in its surface (FIG. 5C).

This substrate is placed in an HVPE furnace, to grow thereover a 500 μm thick GaN layer 18 (FIG. 5D). The material for the growth uses NH₃ and GaCl, and the carrier gas uses a mixture of N₂ and H₂ gases. The growth conditions of the GaN layer 18 are: normal pressure and 1040° C. substrate temperature. The crystal growth velocity of the HVPE is about 2120 μm/h. After the growth of the GaN layer 18 ends, in the cooling process, the GaN layer 18 is spontaneously separated at the void layer 16 from the sapphire substrate 11, which results in a GaN self-standing substrate 19.

The GaN self-standing substrate 19 obtained is convexly warped to its back surface, while being in a concave shape on its surface to reflect the warped shape of the back surface (FIG. 5E).

Next, the back surface of the GaN self-standing substrate 19 obtained is flattened with a diamond grindstone polishing machine, and to remove fabrication strain, the back surface is slightly etched by immersion in a heated potassium hydroxide solution. Also, a chamfering machine is used to trim the substrate to have the diameter φ=50.8 mm. Consequently, a GaN self-standing substrate 20 with film thickness distribution being thin in the middle and thick in the periphery is obtained (FIG. 5F). When the thickness of the GaN self-standing substrate 20 is measured with a dial gauge, it is 318 μm in its middle, and 345 μm in its peripheral thickest portion.

The back surface (flat surface) of this substrate is taken as the reference plane. The c-axis inclination distribution in the substrate surface is obtained by X-ray diffraction measurement. It is found that the c-axis inclination distribution measured at 5 points in the plane of the substrate is such that the c-axes are all directed to One point on the periphery of the substrate, to reflect the off-angle of the underlying sapphire and the warpage of the substrate, having variations of +0.35° to +0.65° in the plane.

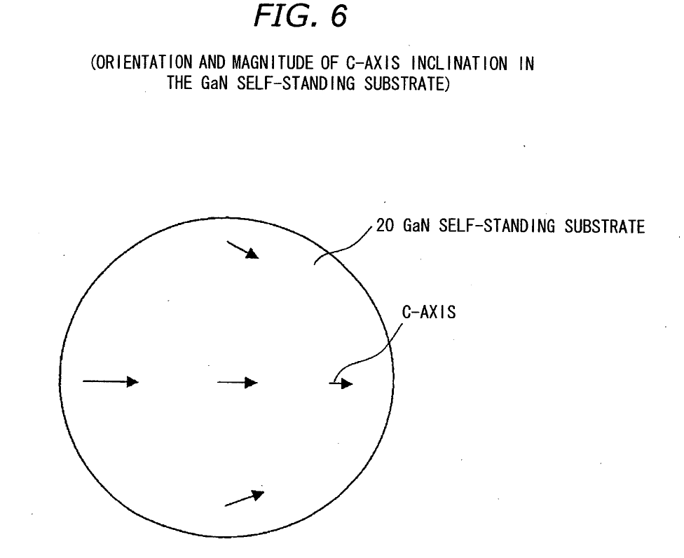

FIG. 6 shows c-axis inclination distribution obtained from the measurements of this GaN self-standing substrate 20. The arrows in the figure show a vector indicating a c-axis inclination of the crystal at that point, where the direction of the arrows denotes the inclination and the length thereof the magnitude of the inclination.

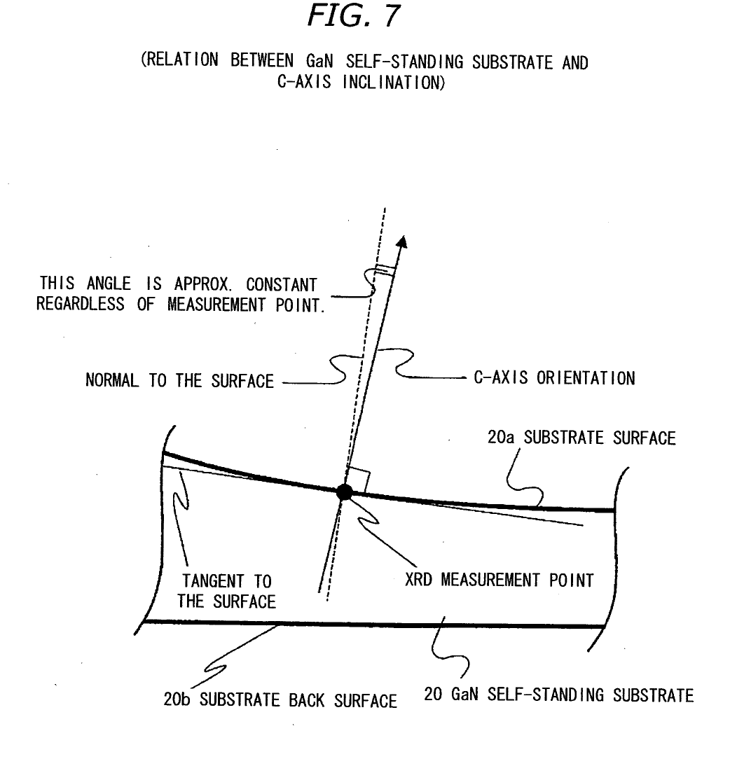

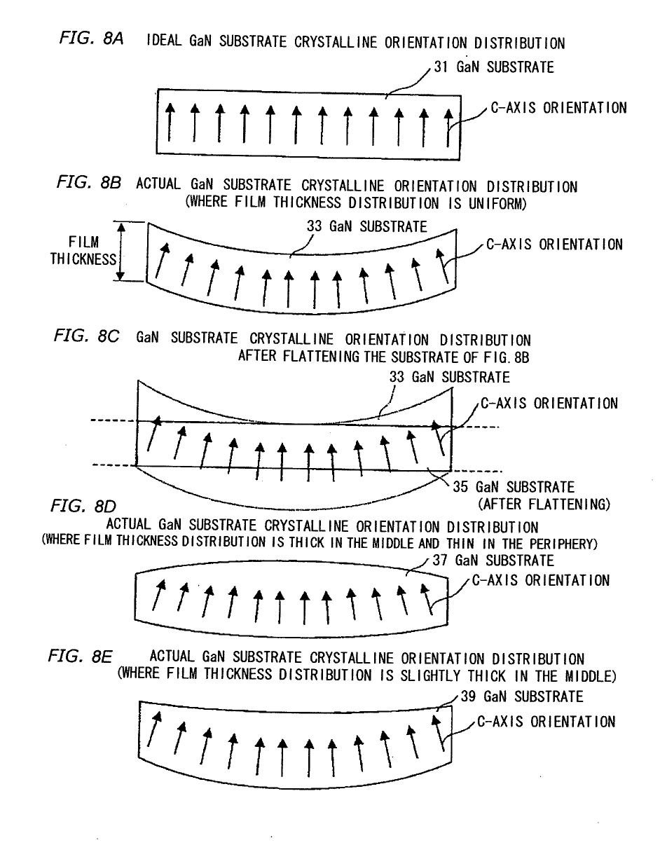

The c-axes of the crystal relative to the back surface flat surface form the inclination distribution as shown in FIG. 6. Because of the concavely warped substrate surface, the c-axis inclinations at the measurement points are always at substantially 0.5° to the substrate surface at any position of the substrate. This relation will be explained based on FIG. 7.

FIG. 7 shows the relation between the substrate and measured c-axis inclination in the GaN self-standing substrate 20. As shown, the c-axis of the GaN crystal measured at the substrate surface 20a is inclined relative to the substrate back surface 20b, so that the direction and magnitude of the inclination are different at each measurement point. But the c-axis is always held in the substantially constant direction at any measurement point to the tangent thereat to the substrate surface 20a.

When the dislocation density of this GaN self-standing substrate 20 is evaluated with the dark spot density of cathode luminescence, it is 2.5×10⁶ cm⁻² in the substrate middle and 2.1×10⁶ cm⁻² on average of 9 points in the plane. Also, calculation of the carrier concentration of the GaN self-standing substrate 20 from substrate sheet resistance obtained by eddy-current measurement, mobility and substrate thickness yields 9.1×10¹⁷ cm⁻³. Although Example 3 causes no doping gas to flow during crystal growth by HVPE, it shows such a high carrier concentration because of Si auto-doping from quartz which constitutes the furnace.

### Modifications

The invention has been described in detail by way of the examples above. These are exemplary, and various modifications such as process combinations may be made. It is apparent to those skilled in the art that such modifications fall within the range of the invention. For example, although in the examples the GaN crystal growth is performed by HVPE, MOVPE may be partially combined therewith in the GaN crystal growth.

Also, in the initial or halfway stage of the crystal growth, to perform the growth with plural uneven portions formed in the crystal growth interface, well-known ELO (epitaxial lateral overgrowth) may be combined that uses a SiO₂ mask, or the like.

Also, although in the examples the underlying substrate uses the sapphire substrate, conventional GaN-based epitaxial layer substrates, such as those of GaAs, Si, ZrB₂, ZnO, etc., are all applicable.

Further, although in the examples the Si-doped GaN self-standing substrate fabrication process is illustrated, it may be applied to undoped, or other dopant, such as Mg, Fe, S, O, Zn, Ni, Cr, Se, etc., doped GaN self-standing substrates.

Also, although in the examples the GaN self-standing substrate fabrication process is illustrated, it may be applied to an AlGaN self-standing substrate.

Although in the examples the substrate is shown as concavely warped to its surface, the invention may be applied to a substrate convexly warped to its surface. In this case, the film thickness relation in the middle and periphery of the substrate described in the examples only has to be considered converse.

Also, although the invention is applied to the nitride-based group III-V semiconductor (e.g., GaN) self-standing substrate, the technical idea of the invention may be applied to underlying substrate-attached GaN-based epitaxial substrates (templates).

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A nitride-based group III-V semiconductor substrate, comprising:
an as-grown surface on a surface of the substrate; and
a flat surface on a back surface of the substrate,
wherein a c-axis of a nitride-based group III-V semiconductor crystal composing the substrate is oriented substantially perpendicular to the surface of the substrate.

2. The nitride-based group III-V semiconductor substrate according to claim 1, wherein:
the surface of the substrate comprises a concave surface.

3. The nitride-based group III-V semiconductor substrate according to claim 2, wherein:
the concave surface on the surface of the substrate is approximated to a spherical surface, and
an angle difference between a c-axis orientation of the crystal at an arbitrary point on the surface of the substrate and a normal to a tangent to the spherical surface at the arbitrary point is not more than 1°.

4. A nitride-based group III-V semiconductor substrate, comprising:
an as-grown surface on a surface of the substrate; and
a flat surface on a back surface of the substrate,
wherein a c-axis of a nitride-based group III-V semiconductor crystal composing the substrate is inclined at a predetermined angle to the surface of the substrate.

5. The nitride-based group III-V semiconductor substrate according to claim 4, wherein:
the surface of the substrate comprises a concave surface.

6. The nitride-based group III-V semiconductor substrate according to claim 1, wherein:
the substrate comprises a self-standing substrate.

7. The nitride-based group III-V semiconductor substrate according to claim 4, wherein:
the substrate comprises a self-standing substrate.

8. The nitride-based group III-V semiconductor substrate according to claim 1, wherein:
the substrate comprises a substrate to be used for a light-emitting diode.

9. The nitride-based group III-V semiconductor substrate according to claim 4, wherein:
the substrate comprises a substrate to be used for a light-emitting diode.

10. The nitride-based group III-V semiconductor substrate according to claim 1, wherein:
the nitride-based group III-V semiconductor crystal comprises a composition expressed by InₓGa_{y}Al_{1-x-y}N (where 0≦x≦1, 0≦y≦1, and 0≦x+y≦1).

11. The nitride-based group III-V semiconductor Substrate according to claim 4, wherein:
the nitride-based group III-V semiconductor crystal comprises a composition expressed by InₓGa_{y}Al_{1-x-y}N (where 0≦x≦1, 0≦y≦1, and 0≦x+y≦1).

12. The nitride-based group III-V semiconductor substrate according to claim 1, wherein:
the substrate comprises a shape with a diameter of 50 mm or more, a thickness of 200 μm or more in its middle portion, and a difference in thickness of 100 μm or less between the middle portion and its peripheral portion.

13. The nitride-based group III-V semiconductor substrate according to claim 4, wherein:
the substrate comprises a shape with a diameter of 50 mm or more, a thickness of 200 μm or more in its middle portion, and a difference in thickness of 100 μm or less between the middle portion and its peripheral portion.

14. The nitride-based group III-V semiconductor substrate according to claim 1, wherein:
the substrate comprises a carrier concentration of 5×10¹⁷ cm⁻³ or more.

15. The nitride-based group III-V semiconductor substrate according to claim 4, wherein;
the substrate comprises a carrier concentration of 5×10¹⁷ cm⁻³ or more.

16. The nitride-based group III-V semiconductor substrate according to claim 1, wherein:
the substrate comprises a dislocation density of 1×10⁸ cm⁻² or less in the surface.

17. The nitride-based group III-V semiconductor substrate according to claim 4, wherein:
the substrate comprises a dislocation density of 1×10⁸ cm⁻² or less in the surface.

18. A method of fabricating a nitride-based group III-V semiconductor substrate, comprising the steps of:
growing a nitride-based group III-V semiconductor film on a hetero-substrate that comprises a c-plane on its surface, and then depositing a metallic film thereon;
thermally treating the substrate with the metallic film deposited thereon in an atmosphere containing hydrogen gas or hydrogen-containing compound gas, to form a void in the nitride-based group III-V semiconductor film;
depositing a nitride-based group III-V semiconductor crystal thereon;
separating the substrate from the nitride-based group III-V semiconductor crystal, to obtain the nitride-based group III-V semiconductor crystal with a c-axis substantially perpendicular to the surface; and
flattening a back surface of the nitride-based group III-v semiconductor crystal.

19. A method of fabricating a nitride-based group III-V semiconductor substrate, comprising the steps of:
growing a nitride-based group III-V semiconductor film on a hetero-substrate that comprises an off-angle, and then depositing a metallic film thereon;
thermally treating the substrate with the metallic film deposited thereon in an atmosphere containing hydrogen gas or hydrogen-containing compound gas, to form a void in the nitride-based group III-V semiconductor film;
depositing thereon a nitride-based group III-V semiconductor crystal that comprises an off-angle;
separating the substrate from the nitride-based group III-V semiconductor crystal, to obtain the nitride-based group III-V semiconductor crystal with a c-axis inclined at a predetermined angle to the surface; and
flattening the back surface of the nitride-based group III-V semiconductor crystal.

20. The method according to claim 18, wherein:
the depositing step of the nitride-based group III-V semiconductor crystal is performed by HVPE.

21. The method according to claim 19, wherein:
the depositing step of the nitride-based group III-V semiconductor crystal is performed by HVPE.

22. The method according to claim 19, wherein:
the nitride-based group III-V semiconductor crystal comprises a gallium nitride crystal.

23. The method according to claim 19, wherein:
the nitride-based group III-V semiconductor crystal comprises a gallium nitride crystal.

24. The method according to claim 18, wherein:
the hetero-substrate comprises sapphire.

25. The method according to claim 19, wherein:
the hetero-substrate comprises sapphire.

26. A nitride-based group III-V light-emitting device, comprising:
an epitaxial layer formed on the nitride-based group III-V semiconductor substrate as defined in claim 1, the epitaxial layer comprising a nitride-based group III-V semiconductor crystal.

27. A nitride-based group III-V light-emitting device, comprising:
an epitaxial layer formed on the nitride-based group III-V semiconductor substrate as defined in claim 4, the epitaxial layer comprising a nitride-based group III-V semiconductor crystal.
